(19) United States
(12) Patent Application Publication
(10) Pub. No.: US 2011/0168888 A1
(43) Pub. Date: Jul. 14, 2011

(54) WEAK-LENS COUPLING OF HIGH CURRENT ELECTRON SOURCES TO ELECTRON MICROSCOPE COLUMNS

(75) Inventors: Bryan W. Reed, Livermore, CA (US); Richard M. Shuttlesworth, Brentwood, CA (US); Thomas B. Lagrange, Brentwood, CA (US); David J. Gibson, San Francisco, CA (US)

(73) Assignee: Lawrence Livermore National Security, LLC, Livermore, CA (US)

(21) Appl. No.: 12/987,803

(22) Filed: Jan. 10, 2011

Related U.S. Application Data
(60) Provisional application No. 61/293,983, filed on Jan. 11, 2010.

(51) Int. Cl. G01N 23/04; H01J 37/26

(52) U.S. Cl. 250/307; 250/311

(57) ABSTRACT

A dynamic transmission electron microscope (DTEM) according to one embodiment includes an electron gun positioned at a top of a column for emitting electrons; an accelerator for accelerating the electrons; a C0 lens positioned below the accelerator for focusing greater than about 95% of the electrons exiting the accelerator; a drift space positioned below the C0 lens; a condenser lens system positioned below the drift space; and a camera chamber positioned below the condenser lens system, the camera chamber for housing a single electron sensitive camera. Additional systems and methods are also presented.

### RELATED APPLICATIONS

The present application claims priority to a U.S. Provisional Patent Application filed Jan. 11, 2010, under Appl. No. 61/293,983, which is incorporated herein by reference.

The United States Government has rights in this invention pursuant to Contract No. DE-AC52-07NA27344 between the United States Department of Energy and Lawrence Livermore National Security, LLC for the operation of Lawrence Livermore National Laboratory.

### FIELD OF THE INVENTION

The present invention relates to electron microscopes, and more particularly, to using a weak lens in an electron microscope.

### BACKGROUND

Most biological processes, chemical reactions, and materials dynamics occur at rates much faster than can be captured with standard video rate acquisition methods in a transmission electron microscope (TEM). Thus, there is a need to increase the temporal resolution in order to capture and understand salient features of these rapid materials processes.

In a conventional TEM, it is rarely desirable to use more than a very small probe current (generally in the nA range), and fixed apertures (typically 1 mm or less in diameter) are set in place to block excess electrons. The beam exiting an accelerator may be several millimeters wide, so that 90% or more of the beam current is eliminated and not used. This is a very reasonable design space for a conventional TEM (it makes the column easy to align, enables large probe demagnifications with low aberrations, and allows sufficient current and coherence for conventional TEM use). A Single-shot dynamic transmission electron microscope (DTEM), however, must obtain a complete real-space image or diffraction pattern in a very short time (e.g., 10 ns), therefore, a DTEM must make use of all or substantially all the available current provided in the system.

Removing the fixed apertures does not provide much relief from the aspect of current propagation, since the off-axis electrons become badly aberrated by the first condenser lens (C1). It would be much better to be able to capture virtually all, of the electrons that come out of the electron gun, especially since every electron that is generated produces space charge fields that reduce the electron gun's performance. For DTEM applications, it is generally better to either use an electron or to not generate the electron in the first place. Generating an electron and not using it is not a desirable outcome for a DTEM.

Therefore, a DTEM which overcomes the issues associated with current TEMs such that it can provide sufficient beam current which allows for single-shot DTEM applications would be beneficial and, groundbreaking in the field of electron microscopy.

### SUMMARY

A dynamic transmission electron microscope (DTEM) according to one embodiment includes an electron gun positioned at a top of a column for emitting electrons; an accelerator for accelerating the electrons; a C0 lens positioned below the accelerator for focusing greater than about 95% of the electrons exiting the accelerator; a drift space positioned below the C0 lens; a condenser lens system positioned below the drift space; and a camera chamber positioned below the condenser lens system, the camera chamber for housing a single electron sensitive camera.

A method for producing a dynamic transmission electron microscope (DTEM) image according to one embodiment includes emitting an electron pulse comprising electrons directed toward an accelerator; accelerating the electrons using the accelerator; redirecting greater than about 95% of the electrons exiting the accelerator toward an area near a center of a C1 lens using a C0 lens without introducing significant aberrations; and capturing an image of a sample using a single electron sensitive camera.

Other aspects and embodiments of the present invention will become apparent from the following detailed description, which, when taken in conjunction with the drawings, illustrate by way of example the principles of the invention.

### BRIEF DESCRIPTION OF THE DRAWINGS

FIG. 1 is a schematic diagram of a dynamic transmission electron microscope (DTEM), according to one embodiment.

FIG. 2 is a plot of transverse beam profiles (scaled projections onto the x-axis), according to one embodiment.

FIG. 3 is a flow diagram of a method for producing a DTEM image, according to one embodiment.

FIG. 4 shows a path for an electron beam through a DTEM, according to one embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a” “an” and “the” include plural referents unless otherwise specified.

In one general embodiment, a dynamic transmission electron microscope (DTEM) includes an electron gun positioned at a top of a column for emitting electrons; an accelerator for accelerating the electrons; a C0 lens positioned below the accelerator for focusing greater than about 95% of the electrons exiting the accelerator; a drift space positioned below the C0 lens; a condenser lens system positioned below the drift space; and a camera chamber positioned below the condenser lens system, the camera chamber for housing a single electron sensitive camera.

In another general embodiment, a method for producing a dynamic transmission electron microscope (DTEM) image includes emitting an electron pulse comprising electrons directed toward an accelerator; accelerating the electrons using the accelerator; redirecting greater than about 95% of the electrons exiting the accelerator toward an area near a center of a C1 lens using a C0 lens without introducing significant aberrations; and capturing an image of a sample using a single electron sensitive camera.

A dynamic transmission electron microscope (DTEM) is a transmission electron microscope (TEM) modified for extremely high time resolution (such as on the nanosecond scale). A DTEM normally operates at very high currents in comparison to a standard TEM (mA scale for DTEM as opposed to μA or nA scale for TEM) in order to obtain a high quality image or a diffraction pattern in a single pulse (“single-shoe”). While a laser-driven photocathode can supply the required brightness and current, in a conventional TEM design most of the electrons are either blocked by apertures or excessively aberrated by the condenser lenses, so that only a small fraction of the current can be effectively transferred to the sample.

The coupling problem previously described has limited the ability of DTEMs to provide nanosecond resolution. This problem may be addressed, however, using embodiments described herein. TEM manufacturers have positioned an additional condenser lens, in various models, to enable, for example, greater flexibility in terms of controlling probe size and beam parallelism at the sample. However, these extra lenses have always been narrow-bore, relatively strong lenses very much like the other condenser lenses in the system, and these systems have always been designed to eliminate most of the beam current for use with fixed apertures.

According to one embodiment, this coupling problem may be solved, allowing the transfer of very large currents from the electron gun to the sample without introducing significant condenser lens aberrations. To solve this coupling problem, a weak, large-bore magnetic lens (dubbed a “C0 lens” herein, since it is positioned before the existing C1 and C2 condenser lenses of a standard TEM) followed by a drift space may be positioned between the accelerator and the C1 lens. Most of the TEM column behaves exactly as it would without the C0 lens; however, the positioning of the C0 lens before the C1 lens has surprisingly enabled the first single shot 15 ns images of individual dislocations in steel to be taken with a DTEM. However, the embodiments disclosed herein are operable at many different time ranges, as images are capable of being produced using single shots of various durations, such as about 1 μs, 10 μs, 5 ns, 10 ns, etc. For example, a DTEM according to embodiments described herein may operate at between about 1 ns and about 5 ns, between about 1 μs and about 10 μs, at less than about 10 μs, at less than about 5 ns, etc.

The DTEM C0 lens, according to various embodiments, is working in an entirely different parameter space than the additional condenser lenses described previously. This causes the electron-optical function of the C0 lens to be distinct from that of any standard or conventional condenser lens system in any typical TEM. In one embodiment, the DTEM C0 lens may operate at about a 48 mm bore diameter, about a 150-200 mm focal length, and about a 200 mm post-lens drift space. In contrast, most TEM lenses operate at focal lengths around 2 mm to 30 mm, in some cases about 10 times smaller than the C0 lens, or less. Of course, in additional embodiments, the DTEM C0 lens may operate at a focal length of about 50 mm, about 400 mm, or anywhere in between or outside of these values. However, operating the DTEM C0 lens at a focal length of less than about 30 mm would force the C0 lens to perform a different sort of function in the DTEM, one which is capable of being performed with standard condenser lenses and it may lose its ability to handle large-diameter beams with low aberrations. Accordingly, some shorter focal lengths are appropriate for the condenser lenses while some larger focal lengths are appropriate for the C0 lens, but a clear distinction between the two regimes in terms of focal length is not a definitive number, but instead may be implementation-dependent and vary based on other parameters of the DTEM.

One purpose of the C0 lens is to capture virtually all (e.g., greater than about 80%, greater than about 90%, greater than about 95%, greater than about 99%, etc.) of the electrons exiting the accelerator and redirect them into a small area near the center of the C1 lens, without introducing significant aberrations. No standard or conventional condenser lens is capable of providing this sort of functionality. A conventional condenser lens system is designed to image the electrons near the center of the transverse phase space onto the specimen of interest, controlling emittance and aberration effects through the use of apertures. A condenser lens system with a C0 lens, on the other hand, may be designed, according to embodiments described herein, to image the electrons from a majority of the transverse phase space, so that the emittance is controlled by the properties of the electron gun, and aberration effects are minimized through appropriate electron-optical design. Part of the appropriate design involved in this implementation is a large bore size, large pole-piece gap, long focal length, and long drift length, (as compared to conventional condenser lenses) significantly out of the range typically employed in TEM condenser lens systems. Once the system is relying on small apertures to improve beam quality, it becomes a conventional system and not a C0-based system. The C0-based system can be operated in a conventional regime, but a standard system cannot be operated in a C0-based system regime without significant degradation of performance.

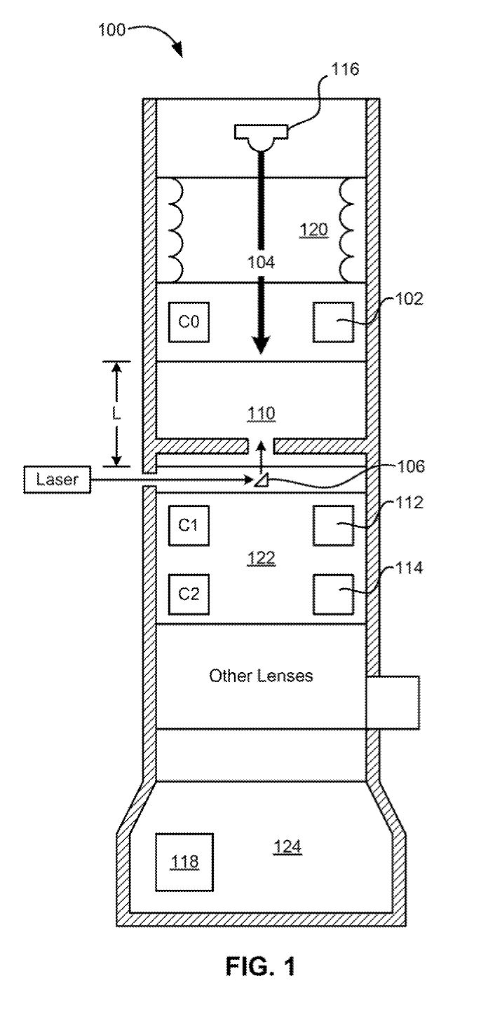

Now referring to FIG. 1, a DTEM 100, according to one embodiment, may include an electron gun 116 positioned at a top of a column for emitting electrons 104, an accelerator 120 for accelerating the electrons 104, a C0 lens 102 (such as a weak, large-bore magnetic condenser lens) positioned below the accelerator 120 for focusing greater than about 95% of the electrons 104 exiting the accelerator 120, a drift space 110 positioned below the C0 lens 102, a condenser lens system 122 positioned below the drift space 110, and a camera chamber 124 positioned below the condenser lens system 122, the camera chamber 124 for housing a single electron sensitive camera 118. Other lenses between the condenser lens system 122 and the camera chamber 124 implement the various real-space imaging and diffraction modes and would incorporate a mechanism for holding a material sample of interest, as would be understood by one of skill in the art.

The accelerator 120 may be a 200 kV accelerator according to one embodiment, as would be understood by one of skill in the art.

According to one embodiment, the C0 lens 102 may have a bore diameter in a range from about 44 mm to about 52 mm, such as about 48 mm. Of course, other diameters are possible, and will be proportional to the overall vertical length of the DTEM, according to various embodiments.

According to another embodiment, the C0 lens 102 may have a focal length in a range from about 50 mm to about 400 mm, such as about 175 mm. Of course, other focal lengths are possible, and will be proportional to the overall vertical length of the DTEM and desired focusing of the condenser lens system 122, according to various embodiments.

In one approach, the drift space 110 may have a vertical length in a range from about 15 cm to about 40 cm, such as about 20 cm. Of course, other lengths are possible, and will be proportional to the overall vertical length of the DTEM, according to various embodiments.

In another approach, the C0 lens 102 may be adapted for focusing electrons 104 exiting the accelerator 120 which are in an electron beam having a diameter of at least about 5 mm. This allows for substantially all of the electrons 104 exiting the accelerator 120 to be captured by the C0 lens 102, in one approach.

As shown in FIG. 1, according to one embodiment, the condenser lens system 122 may include a C1 lens 112 positioned below the C0 lens 102, and a C2 lens 114 positioned below the C1 lens 112. In a further embodiment, the C0 lens 102 may be adapted for redirecting the electrons 104 exiting the accelerator 120 toward an area near a center of the C1 lens 112 without introducing significant aberrations.

In a preferred embodiment, the DTEM may be capable of obtaining a complete real-space image or diffraction pattern in less than about 20 ns, less than about 15 ns, less than about 10 ns, less than about 5 ns, less than about 1 ns, in a range from about 1 ns to about 5 ns, in a range from about 1 μs to about 10 μs, etc., e.g., it is a single-shot DTEM as would be understood by one of skill in the art.

The structure shown in FIG. 1 may be used for DTEM, according to one embodiment. A weak, large-bore magnetic condenser lens 102, referred to as C0 because it precedes the relatively standard condenser lenses C1 112 and C2 114, is positioned after the accelerator 120 in a DTEM apparatus 100. A long drift space 110 may be added below the C0 lens 102, giving the beam time to smoothly re-converge before reaching the laser mirror 106. In one embodiment, the drift space may have a length in a range of between about 14 cm and about 40 cm, such as about 20 cm. A laser mirror 106, which may have about a 1 mm aperture, in some embodiments, is positioned after the drift space. In one approach, a two-dimensional magnetic deflector 108 may be positioned about midway through the drift space, facilitating alignment between the C0 and C1 lenses 102 and 112. In order to implement the drift space, a drift space 110 may be used having a center-formed hole to allow an electron beam to pass therethrough. This drift space 110 may comprise any material suitable for blocking x-rays and other sources of electro-magnetic interference, such as brass, and may have a length in a range between about 5 cm and about 20 cm, such as about 10 cm. The drift space 110 may include the 45° mirror 106, preferably near a bottom end thereof, and vacuum ports, such as for diagnostics.

The C0 lens 102 may have an extremely wide bore (about 5 cm in one embodiment) and long focal length (about 15 cm in one embodiment), more than a factor of ten larger than the same quantities for a typical TEM condenser lens. This is an appropriate design to minimize the effect of aberrations when a lens is intended to smoothly reconverge a very broad, moderately divergent beam. This is a very different role from those of the objective and projector lenses, which usually provide the best performance with small polepiece gaps and short focal lengths. The magnetic field and magnetic field gradients in the C0 lens are quite small, and it can capture and re-focus even a very wide beam (up to 5 mm diameter) without introducing large aberration effects.

The beam is less than about 1 mm in diameter as it enters the C1 lens 112, so if the system is well aligned then the C1 lens' aberrations will also introduce relatively little emittance growth.

A typical illumination spot for a DTEM operated in conventional mode (i.e., with thermionic emission and the C0 lens 102 off) without a C2 lens 114 aperture, focused to a paraxial crossover consists of a spot having a very intense central region surrounded by a much broader halo of aberrated electrons. The halo is asymmetric, due to difficult-to-correct mechanical misalignment of fixed apertures. Most of these aberrations are produced by the C1 lens 112 (as was verified by noting the effect of the C1 excitation on the measured halo), and the aberrated and asymmetrically apertured electrons can be removed by inserting a C2 lens 114 aperture. This situation is familiar to all TEM operators.

Lens aberrations cause a marked sigmoidal curvature in the calculated phase space distribution, making it impossible to simultaneously focus the paraxial and marginal electrons. The C2 lens 114 aperture eliminates all but the nearly-paraxial electrons, enabling a tight focus (limited by the beam temperature and source size and not by aberrations) while also providing a direct way to control the angular range (which is important for producing high-resolution images and diffraction patterns).

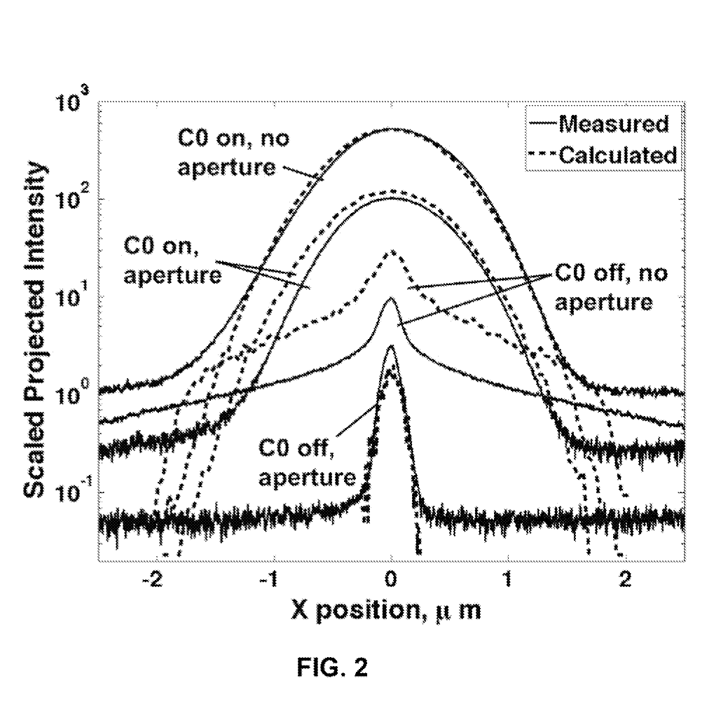

Calculated spatial profiles in FIG. 2 seem to match experimental measurements quite well, apart from a factor of about 3 in the intensity of the low-current (C0 off) no-aperture case. This discrepancy may be partly explained by possible misalignment (throughput being very sensitive to gun alignment when the instrument is operated in this way), but is also probably partly derived from known limitations in the model. In any case, FIG. 2 indicates that the operation of the C0 lens in the context of the complete condenser lens system is fairly well understood.

It has been found that about a 20 cm drift section after the C0 lens (which increased the total column height by nearly 30 cm) was an acceptable compromise between the electron optical performance and practical considerations in the implementation of a DTEM. These considerations included seismic stability, the difficulty of extending the vacuum system and hydraulic gun lift, and ultimately the height of any room in which the instrument would be operated.

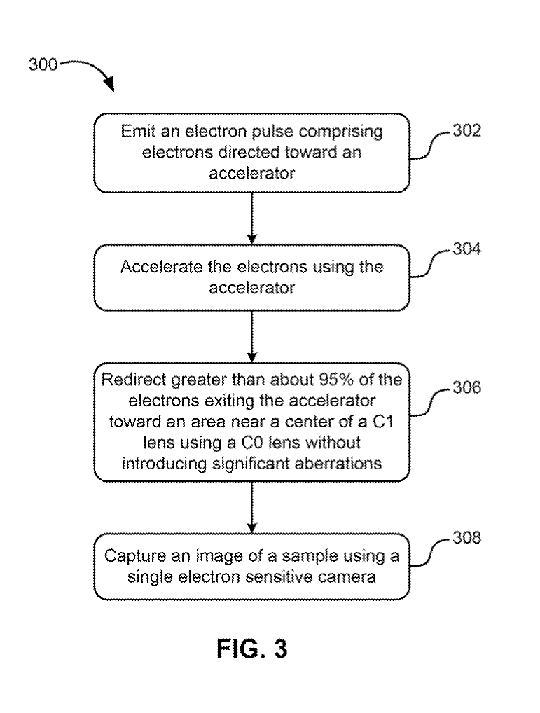

Now referring to FIG. 3, a method 300 for producing a DTEM image is shown according to one embodiment. The method 300 may be carried out in any desired environment, and may include embodiments and/or approaches toward the design and utilization of a DTEM as described in FIGS. 1-2, according to various embodiments. Of course, the method 300 may include more or less operations than those shown in FIG. 3 and described below.

In operation 302, an electron pulse is emitted comprising electrons directed toward an accelerator. The electron pulse may be emitted for a brief duration of time, such as less than about 20 ns, less than about 15 ns, less than about 10 ns, less than about 5 ns, less than about 1 ns, in a range from about 1 ns to about 5 ns, in a range from about 1 μs to about 10 μs, etc., and may be emitted only once in order to capture an image, according to various embodiments.

In operation 304, the electrons are accelerated using the accelerator. The acceleration may be carried out as known in the art, such as with the aid of a 200 kV accelerator, in one embodiment.

In operation 306, greater than about 95% of the electrons exiting the accelerator are redirected toward an area near a center of a C1 lens using a C0 lens without introducing significant aberrations. The C0 lens, according to one embodiment, may be a weak, large-bore magnetic lens.

In operation 308, an image of a sample is captured using a single electron sensitive camera. This image may be a complete real-space image, a diffraction pattern, or any other type of TEM image as would be understood to one of skill in the art upon reading the present descriptions.

In one embodiment, the C0 lens may have a bore diameter in a range from about 44 mm to about 52 mm, such as about 48 mm.

In another embodiment, the C0 lens may have a focal length in a range from about 50 mm to about 400 mm, from about 150 mm to about 200 mm, from about 100 mm to about 250 mm, etc., such as about 175 mm.

In yet another embodiment, the C0 lens may have a post-lens drift in a range from about 150 mm to about 250 mm, such as about 200 mm.

According to one approach, the method 300 may include condensing the electrons by passing the electrons from the C1 lens to a C2 lens positioned below the C1 lens.

In one preferable approach, the electron pulse may be a single electron pulse lasting less than about 15 ns that is capable of producing an image of the sample. In more approaches, the electron pulse may be a single electron pulse lasting less than about 10 ns, less than about 5 ns, less than about 1 ns, in a range from about 1 ns to about 5 ns, in a range from about 1 μs to about 10 μs, etc.

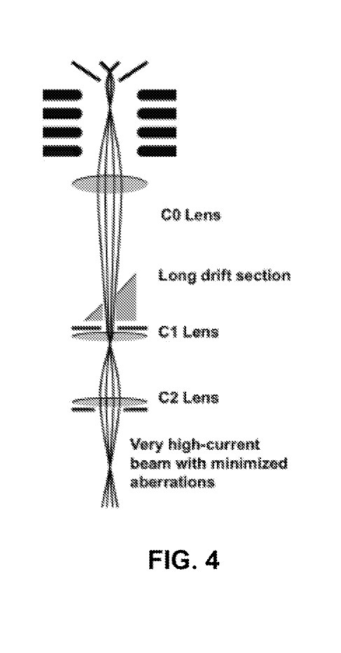

As shown in FIG. 4, a DTEM system, according to embodiments described herein, is designed to solve the coupling problem described herein in order to achieve good performance, which implies some form of weak lensing between the electron gun and the C1 lens. The DTEM with the C0 lens design described herein overcomes the coupling problem by adding components, obviating the need to perform difficult modifications to the acceleration, electron gun, and/or existing lens systems in conventional TEMs. Any single-shot high performance DTEM needs to somehow account for the coupling problems described herein. The C0 lens described herein may be used to overcome these problems, and is a direct method of adding the necessary functionality to TEMs where the existing gun lens system cannot perform the coupling function. Embodiments described herein may be useful in other high-current applications, beyond single-shot high performance DTEMs, such as high-throughput imaging and analytical TEM applications (e.g., low spatial resolution energy dispersive x-ray spectroscopy, energy-loss filtered imaging, etc.).

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A dynamic transmission electron microscope (DTEM), comprising:
an electron gun positioned at a top of a column for emitting electrons;
an accelerator for accelerating the electrons;
a C0 lens positioned below the accelerator for focusing greater than about 95% of the electrons exiting the accelerator;
a drift space positioned below the C0 lens;
a condenser lens system positioned below the drift space; and
a camera chamber positioned below the condenser lens system, the camera chamber for housing a single electron sensitive camera.

2. The DTEM as recited in claim 1, wherein the C0 lens has a bore diameter in a range from about 44 mm to about 52 mm.

3. The DTEM as recited in claim 2, wherein the C0 lens' bore diameter is about 48 mM.

4. The DTEM as recited in claim 1, wherein the C0 lens has a focal length in a range from about 50 mm to about 400 mm.

5. The DTEM as recited in claim 4, wherein the C0 lens' focal length is about 175 mM.

6. The DTEM as recited in claim 1, wherein the drift space has a vertical length in a range from about 15 cm to about 40 cm.

7. The DTEM as recited in claim 6, wherein the drift space's length is about 20 cm.

8. The DTEM as recited in claim 1, wherein the C0 lens is adapted for focusing electrons exiting the accelerator which are in an electron beam having a diameter of at least about 5 mm.

9. The DTEM as recited in claim 8, wherein the C0 lens has a bore diameter in a range from about 44 mm to about 52 mm and a focal length in a range from about 150 mm to about 200 mm, and wherein the drift space has a vertical length in a range from about 15 cm to about 40 cm.

10. The DTEM as recited in claim 1, wherein the condenser system comprises:
a C1 lens positioned below the C0 lens; and
a C2 lens positioned below the C1 lens.

11. The DTEM as recited in claim 10, wherein the C0 lens is adapted for redirecting the electrons exiting the accelerator toward an area near a center of the C1 lens without introducing significant aberrations.

12. The DTEM as recited in claim 1, wherein the DTEM is capable of obtaining a complete real-space image or diffraction pattern in less than about 15 ns.

13. The DTEM as recited in claim 1, wherein the DTEM is capable of obtaining a complete real-space image or diffraction pattern in less than about 5 ns.

14. A method for producing a dynamic transmission electron microscope (DTEM) image, the method comprising:
emitting an electron pulse comprising electrons directed toward an accelerator;
accelerating the electrons using the accelerator;
redirecting greater than about 95% of the electrons exiting the accelerator toward an area near a center of a C1 lens using a C0 lens without introducing significant aberrations; and
capturing an image of a sample using a single electron sensitive camera.

15. The method as recited in claim 14, wherein the C0 lens has a bore diameter in a range from about 44 mm to about 52 mm.

16. The method as recited in claim 15, wherein the C0 lens' bore diameter is about 48 mM.

17. The method as recited in claim 14, wherein the C0 lens has a focal length in a range from about 50 mm to about 400 mm.

18. The method as recited in claim 17, wherein the C0 lens' focal length is about 175 mM.

19. The method as recited in claim 14, wherein the C0 lens has a post-lens drift space with a length in a range from about 150 mm to about 250 mm.

20. The method as recited in claim 19, wherein the C0 lens' post-lens drift space length is about 200 mm.

21. The method as recited in claim 14, further comprising condensing the electrons by passing the electrons from the C1 lens to a C2 lens positioned below the C1 lens.

22. The method as recited in claim 14, wherein the electron pulse is a single electron pulse in a range lasting from about 1 ns to about 15 ns that is capable of producing an image of the sample.
